(19) United States
(12) Patent Application Publication
(10) Pub. No.: US 2024/0203762 A1
(43) Pub. Date: Jun. 20, 2024

(54) SEMICONDUCTOR MANUFACTURING APPARATUS

(71) Applicant: Kioxia Corporation, Tokyo (JP)

(72) Inventors: Kohei NAKAMURA, Yokkaichi Mie (JP); Kazufumi NOMURA, Yokkaichi Mie (JP); Aoi SUZUKI, Yokkaichi Mie (JP); Yoshinori ODA, Yokkaichi Mie (JP)

(73) Assignee: Kioxia Corporation, Tokyo (JP)

(21) Appl. No.: 18/532,176

(22) Filed: Dec. 7, 2023

(30) Foreign Application Priority Data
Dec. 16, 2022 (JP) 2022-201523

(51) Int. Cl. H01L 21/67; H01L 21/687

(52) U.S. Cl. CPC H01L 21/67092; H01L 21/67253; H01L 21/68785

(57) ABSTRACT

A semiconductor manufacturing apparatus according to the present embodiment includes a table, a shaft, a sensor, and a first control unit. The table has a first surface on which a processing target object is placed, and is rotatable about a rotational axis in a first direction substantially orthogonal to the first surface. The shaft rotatably and movably holds a blade that machines the processing target object. The sensor measures a thickness of processing target object in a region to be machined by the blade. The first control unit controls rotation and movement of the shaft. The first control unit controls movement of the blade in the first direction based on a result of the measurement by the sensor.

### CROSS-REFERENCE TO RELATED APPLICATIONS

This application is based upon and claims the benefit of priority from the prior Japanese Patent Application No. 2022-201523, filed on Dec. 16, 2022, the entire contents of which are incorporated herein by reference.

### FIELD

The embodiments of the present invention relate to a semiconductor manufacturing apparatus.

### BACKGROUND

In a semiconductor apparatus manufacturing process, an outer peripheral end part of a semiconductor wafer is removed (edge-trimmed) up to a predetermined depth in some cases. The trimming is performed by, for example, machining using a blade.

### BRIEF DESCRIPTION OF THE DRAWINGS

FIG. 1 is a diagram illustrating an example of the configuration of a semiconductor manufacturing apparatus according to a first embodiment;

FIG. 2 is a top view illustrating an example of the configuration of a table according to the first embodiment;

FIG. 3 is a cross-sectional view illustrating the example of the configuration of the table according to the first embodiment;

FIG. 4A is a diagram illustrating an example of operation of the semiconductor manufacturing apparatus according to the first embodiment;

FIG. 4B is a diagram illustrating the example of operation of the semiconductor manufacturing apparatus, following FIG. 4A;

FIG. 4C is a diagram illustrating the example of operation of the semiconductor manufacturing apparatus, following FIG. 4B;

FIG. 4D is a diagram illustrating the example of operation of the semiconductor manufacturing apparatus, following FIG. 4C;

FIG. 4E is a diagram illustrating the example of operation of the semiconductor manufacturing apparatus, following FIG. 4D;

FIG. 5 is a diagram illustrating an example of the amount of downward movement of a blade according to a first comparative example;

FIG. 6 is a diagram illustrating an example of abrasion of the blade according to the first comparative example;

FIG. 7 is a diagram illustrating an example of back grind of a semiconductor wafer according to the first comparative example;

FIG. 8 is a cross-sectional view illustrating an example of a semiconductor wafer according to a second comparative example;

FIG. 9 is a cross-sectional view illustrating an example of the configuration of a table according to a second embodiment;

FIG. 10 is a top view illustrating an example of the configuration of a table according to a third embodiment; and

FIG. 11 is a cross-sectional view illustrating the example of the configuration of the table according to the third embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor manufacturing apparatus according to the present embodiment includes a table, a shaft, a sensor, and a first control unit. The table has a first surface on which a processing target object is placed, and is rotatable about a rotational axis in a first direction substantially orthogonal to the first surface. The shaft rotatably and movably holds a blade that machines the processing target object. The sensor measures a thickness of processing target object in a region to be machined by the blade. The first control unit controls rotation and movement of the shaft. The first control unit controls movement of the blade in the first direction based on a result of the measurement by the sensor.

### First Embodiment

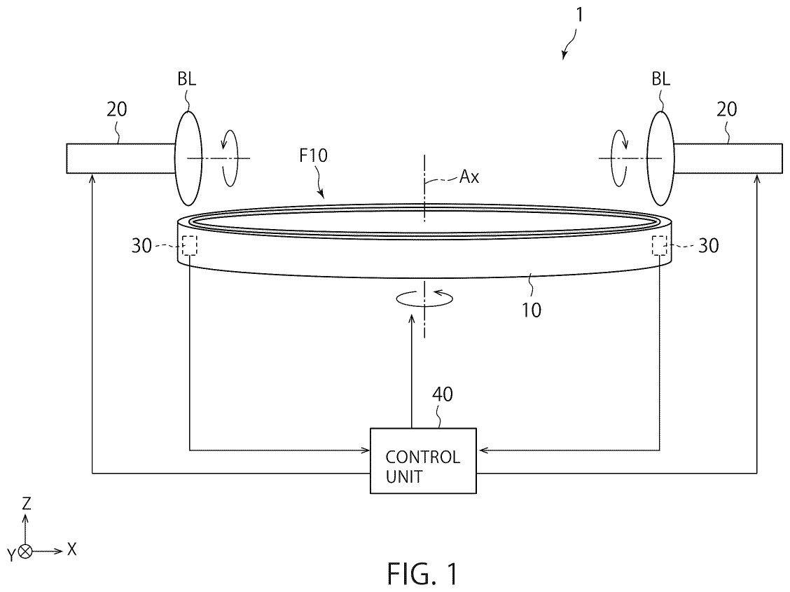

FIG. 1 is a diagram illustrating an example of the configuration of a semiconductor manufacturing apparatus 1 according to a first embodiment. The semiconductor manufacturing apparatus 1 removes, for example, an outer peripheral end part of a semiconductor wafer W up to a predetermined depth (edge trimming). Illustration of the semiconductor wafer W is omitted in FIG. 1. The semiconductor wafer W is, for example, a silicon (Si) wafer. The semiconductor wafer W is an example of a processing target object.

The semiconductor manufacturing apparatus 1 includes a table 10, a shaft 20, a sensor 30, and a control unit 40.

FIG. 1 illustrates an X direction and a Y direction parallel to a front surface of the table 10 and orthogonal to each other, and a Z direction orthogonal to the front surface of the table 10. In the present specification, the positive Z direction is treated as the upward direction, and the negative Z direction is treated as the downward direction. The negative Z direction may be or may not be aligned with the direction of gravity.

The table 10 has a surface F10 on which the semiconductor wafer W is placed. The table 10 is rotatable about a rotational axis in the Z direction substantially orthogonal to the surface F10. The rotational axis of the table 10 is a central axis Ax passing through the center of the surface F10.

The shaft 20 rotatably and movably holds a blade BL that machines the semiconductor wafer W. The shaft 20 is, for example, a spindle.

The sensor 30 measures the thickness of the semiconductor wafer W in a region to be machined by the blade BL. The region to be machined by the blade BL is, for example, the outer peripheral end part of the semiconductor wafer W when viewed in the Z direction.

In the example illustrated in FIG. 1, two blades BL and two shafts 20 are provided. In this case, edge trimming is performed as the table 10 rotates half round.

The sensor 30 measures the thickness of the semiconductor wafer W from the table 10 side, in other words, from a side opposite each blade BL with respect to the semiconductor wafer W. The sensor 30 is provided, for example, in the table 10. The sensor 30 is provided at a position directly below the blade BL.

The sensor 30 is, for example, an optical sensor. More specifically, the sensor 30 is, for example, a spectroscopic interference sensor. The sensor 30 is not limited to an optical sensor but may be an ultrasonic sensor, for example.

The control unit (first control unit) 40 controls rotation and movement of the shaft 20. The control unit 40 also controls movement of the blade BL in the Z direction based on a result of the measurement by the sensor 30. The control unit 40 controls movement of the blade BL in the Z direction during at least one of downward movement of the blade BL at machining start and rotation of the table 10 in machining. Accordingly, machining can be performed more highly accurately.

In addition, the control unit (second control unit) 40 controls rotation of the table 10. The table 10 is rotated after the blade BL is moved downward and part of the outer peripheral end part of the semiconductor wafer W is machined to a desired thickness. Accordingly, edge trimming of the semiconductor wafer W is performed.

The configuration of the table 10 will be described below in detail.

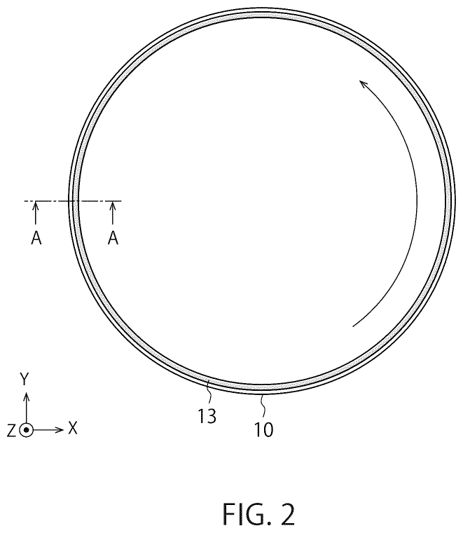

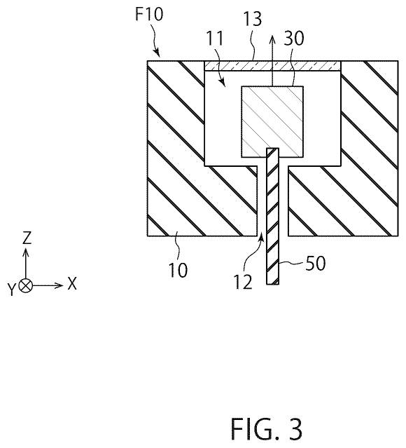

FIG. 2 is a top view illustrating an example of the configuration of the table 10 according to the first embodiment. FIG. 3 is a cross-sectional view illustrating the example of the configuration of the table 10 according to the first embodiment. Line A-A in FIG. 2 indicates a section corresponding to the cross-sectional view in FIG. 3.

As illustrated in FIG. 3, the sensor 30 is provided inside the table 10.

The semiconductor manufacturing apparatus 1 further includes a structural body 50.

The structural body 50 is provided to penetrate through the table 10. In the example illustrated in FIG. 3, the structural body 50 is provided to penetrate from a surface of the table 10, which is opposite the surface F10. The structural body 50 supports the sensor 30. The result of the measurement by the sensor 30 is transmitted to the control unit 40 through a cable (not illustrated) provided along the structural body 50. The structural body 50 is, for example, a column-shaped portion extending straight in the Z direction. The structural body 50 may be in a tubular shape inside which a cable is routed. Alternatively, the structural body 50 may be a cable.

The table 10 includes recessed parts 11 and 12 and a transparent part 13.

The recessed part 11 is provided at the surface F10 such that the sensor 30 is separated from the table 10 that is rotating. The recessed part 11 has a width in the X direction and a depth in the Z direction with which the recessed part 11 can house the sensor 30. The recessed part 11 is an example of a first recessed part.

The recessed part 12 is provided at the surface of the table 10, which is opposite the surface F10. The recessed part 12 has a width in the X direction with which the recessed part 12 can house the structural body 50. The recessed part 12 is connected to the recessed part 11. In other words, the recessed parts 11 and 12 are through-holes of the table 10.

The transparent part 13 is provided between the semiconductor wafer W and the sensor 30. The transparent part 13 is provided along the surface F10. The transparent part 13 contains a material that does not affect the thickness measurement by the sensor 30 as an optical sensor. The transparent part 13 contains, for example, glass.

As illustrated in FIG. 2, the transparent part 13 is provided round an outer periphery near an outer peripheral end part of the table 10. The recessed parts 11 and 12 is provided at a substantially same position as the transparent part 13 in FIG. 2. Thus, the recessed parts 11 and 12 and the transparent part 13 are provided in substantially circular ring shapes centered at the center (central axis Ax) of the table 10 when viewed in the Z direction. The recessed parts 11 and 12 are trenches.

As illustrated in FIG. 3, the sensor 30 and the structural body 50 does not contact the table 10. The sensor 30 is provided independently from the table 10 that is rotating. In other words, the sensor 30 is constantly positioned below the blade BL during rotation of the table 10. Accordingly, the sensor 30 is constantly positioned directly below the blade BL without moving while the table 10 rotates. As a result, the sensor 30 can constantly measure the thickness of the semiconductor wafer W during rotation of the table 10.

Operation of the semiconductor manufacturing apparatus 1 will be described below.

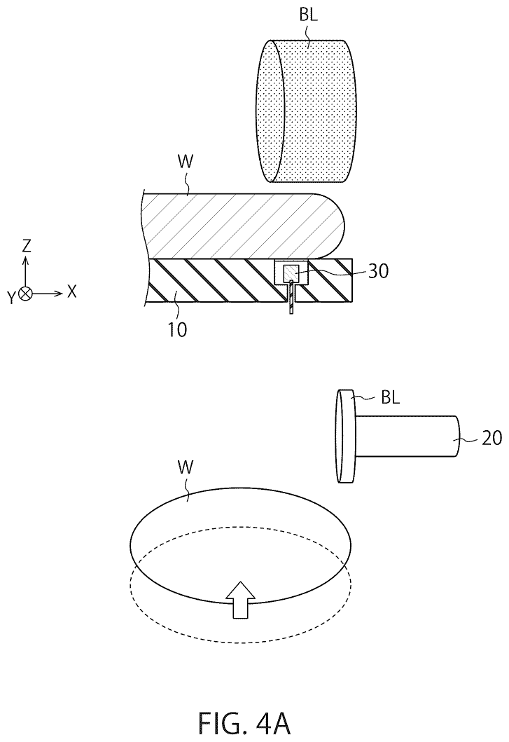

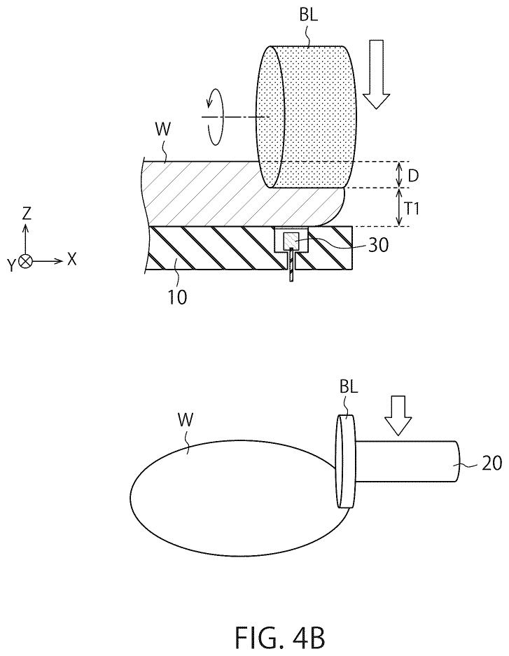

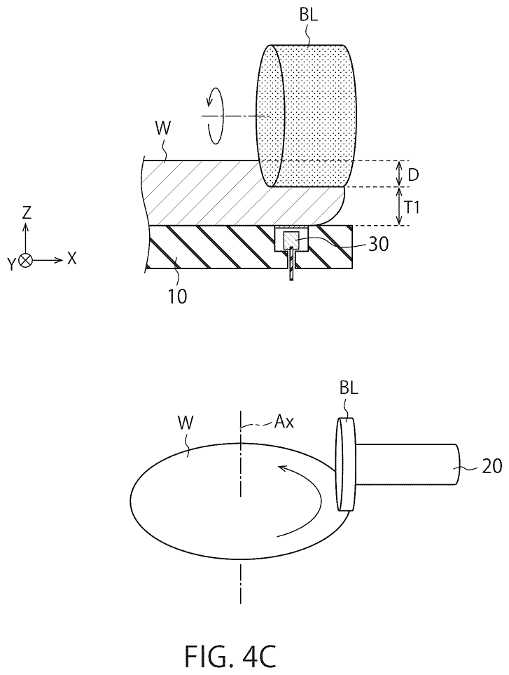

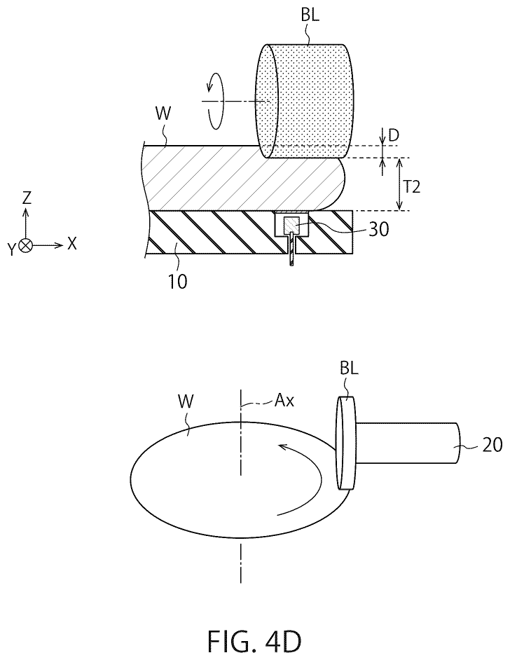

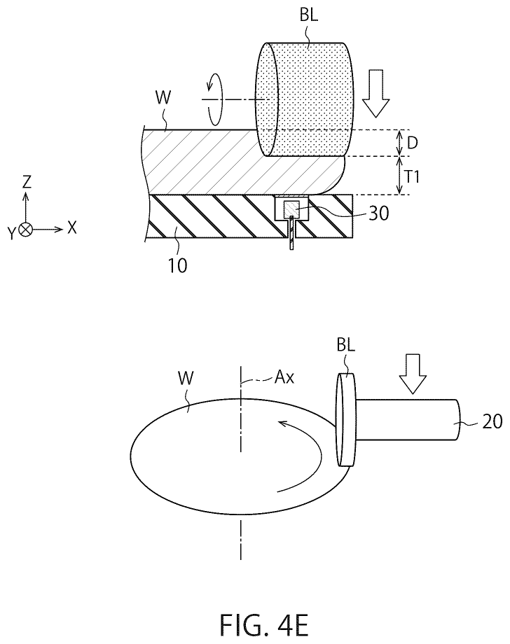

FIGS. 4A to 4E are diagrams illustrating an example of operation of the semiconductor manufacturing apparatus 1 according to the first embodiment. The upper parts of FIGS. 4A to 4E are cross-sectional views of the sensor 30 and its vicinity. The lower parts of FIGS. 4A to 4E are diagrams illustrating the positional relation between the blade BL and the semiconductor wafer W. In FIGS. 4A to 4E, one blade BL and one shaft 20 are illustrated.

The table 10 and the semiconductor wafer W are movable in the Y direction, and the blade BL and the shaft 20 are movable in the X and Z directions.

First, as illustrated in FIG. 4A, the control unit 40 moves the table 10 to move the semiconductor wafer W. The control unit 40 moves the table 10 so that the sensor 30 in the table 10 is positioned directly below the blade BL.

Subsequently, as illustrated in FIG. 4B, the control unit 40 moves downward the blade BL while rotating the blade BL. More specifically, the control unit 40 moves downward the blade BL, which is positioned above the sensor 30, in the Z direction (negative Z direction) while rotating the blade BL during stop of rotation of the table 10. The control unit 40 stops the downward movement of the blade BL when the result of the measurement by the sensor 30 is equal to or smaller than a first predetermined thickness T1. Specifically, the control unit 40 monitors the thickness of the semiconductor wafer W during downward movement of the blade BL, and stops the downward movement of the blade BL at a timing when the result of the measurement by the sensor 30 becomes a designated thickness. In other words, end point sensing of a trimming depth D can be performed. Accordingly, machining can be more highly accurately performed.

Subsequently, as illustrated in FIG. 4C, the control unit 40 starts rotation of the table 10. Specifically, the control unit 40 starts rotation of the table 10 when the result of the measurement by the sensor 30 is equal to or smaller than the first predetermined thickness T1.

The cutting edge of the blade BL is gradually abraded due to machining of the semiconductor wafer W. Since the position of the shaft 20 does not change, the trimming depth D becomes shallower as the cutting edge of the blade BL is abraded. As a result, the thickness (residue thickness) of the semiconductor wafer W remaining after machining, in other words, the result of the measurement by the sensor 30 becomes larger.

Subsequently, as illustrated in FIG. 4D, the thickness of the semiconductor wafer W reaches a second predetermined thickness T2. The second predetermined thickness T2 is thicker than the first predetermined thickness T1.

Subsequently, as illustrated in FIG. 4E, the control unit 40 moves downward the blade BL in the Z direction when the result of the measurement by the sensor 30 is equal to or larger than the second predetermined thickness T2 during rotation of the blade BL and the table 10, in other words, during machining of the semiconductor wafer W. Specifically, the control unit 40 monitors the thickness of the semiconductor wafer W even after the table 10 starts rotating. When the thickness of the semiconductor wafer W is large, the control unit 40 moves downward the blade BL, for example, until the thickness of the semiconductor wafer W becomes equal to the first predetermined thickness T1. The height of an end point of the downward movement of the blade BL is not limited to a height corresponding to the first predetermined thickness T1. Accordingly, the thickness of the semiconductor wafer W can be monitored and adjusted in real time during machining of the semiconductor wafer W. In FIG. 4E, an operation condition such as the downward movement speed of the blade BL is the same as, for example, an operation condition in FIG. 4B.

As described above, according to the first embodiment, the sensor 30 measures the thickness of the semiconductor wafer W in the region to be machined by the blade BL. The control unit 40 controls movement of the blade BL in the Z direction based on the result of the measurement by the sensor 30. Accordingly, machining can be more highly accurately performed.

The number of blades BL, in other words, the number of shafts 20 is not limited to that in the example illustrated in FIG. 1. For example, in a case where the number of blades BL is one, edge trimming is performed as the table 10 rotates one round. In a case where the number of blades BL is four, edge trimming is performed as the table 10 rotates ¼ round.

The number of sensors 30 corresponds to the number of blades BL. For example, one sensor 30 is provided in a case where the number of blades BL is one. Four sensors 30 are provided in a case where the number of blades BL is four.

### First Comparative Example

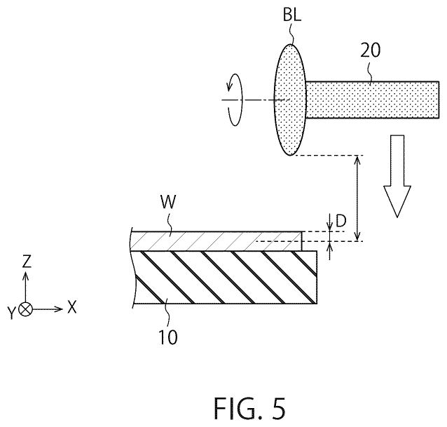

FIG. 5 is a diagram illustrating an example of the amount of downward movement of the blade BL according to a first comparative example.

In a method of controlling the trimming depth D according to the first comparative example, position information of the cutting edge of the blade BL is stored in setup performed right before. The setup includes, for example, attachment and adjustment of an instrument such as the blade BL. In the first comparative example, the relation (difference) between the position information of the cutting edge of the blade BL and an upper surface position of the semiconductor wafer W, which is separately measured, and the amount of downward movement of the blade BL based on the set trimming depth D are determined. However, in this case, the position information of the cutting edge of the blade BL is not updated until the next setup. Accordingly, the amount of downward movement does not change even when the blade BL is abraded and shortened.

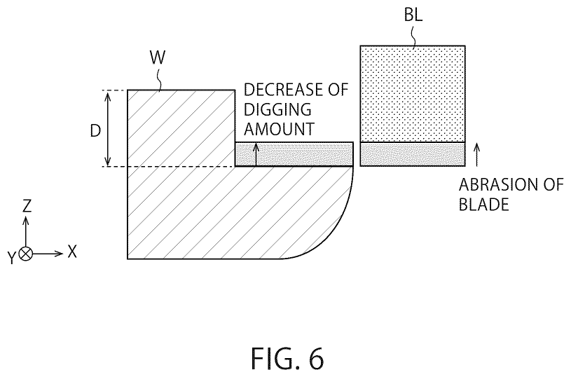

FIG. 6 is a diagram illustrating an example of abrasion of the blade BL according to the first comparative example.

As illustrated in FIG. 6, the trimming depth D becomes shallower as the amount of digging by the blade BL decreases due to abrasion. In this case, the trimming depth D potentially varies in the plane of the semiconductor wafer W or among the semiconductor wafers W. Furthermore, the position of the cutting edge of the blade BL varies by, for example, several μm at each setup in some cases. The accuracy of the trimming depth D decreases due to the variance.

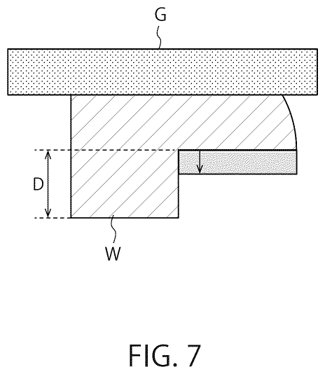

FIG. 7 is a diagram illustrating an example of back grind of the semiconductor wafer W according to the first comparative example.

The back surface (upper surface) of the semiconductor wafer W is polished by a grinder G. During the polishing, chipping potentially occurs at a corner of the semiconductor wafer W. The chipping is break of an end material of the semiconductor wafer W. When the trimming depth D is shallow, the chipping occurs near any semiconductor element (not illustrated) on the lower surface of the semiconductor wafer W illustrated in FIG. 7. This potentially leads to adverse influence on the semiconductor element.

However, in the first embodiment, the thickness of the semiconductor wafer W is monitored by the sensor 30, and the blade BL can be controlled so that the semiconductor wafer W has an appropriate thickness. As illustrated in FIGS. 4D and 4E, variance of the trimming depth D due to abrasion of the blade BL can be prevented by monitoring the thickness of the semiconductor wafer W during machining. As a result, the trimming depth D can be prevented from varying in the plane of the semiconductor wafer W or among the semiconductor wafers W. Moreover, as illustrated in FIG. 4B, variance of the trimming depth D at each setup can be prevented by monitoring the thickness of the semiconductor wafer W at machining start (end point sensing of the trimming depth D). As a result, the trimming depth D can be easily more appropriately ensured, and chipping can be caused at a position separated from any semiconductor element.

### Second Comparative Example

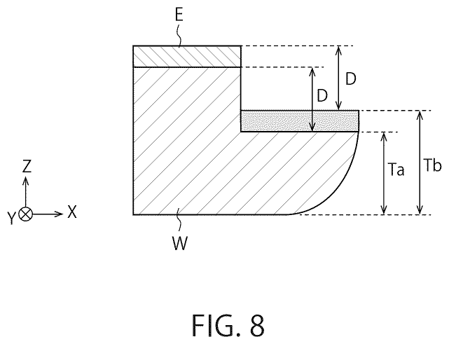

FIG. 8 is a cross-sectional view illustrating an example of the semiconductor wafer W according to a second comparative example.

In the method of controlling the trimming depth D according to the first comparative example, since the upper surface position of the semiconductor wafer W is a reference, the thickness (residue thickness) of the semiconductor wafer W remaining after machining changes as the thickness of a semiconductor element E changes.

FIG. 8 illustrates a thickness Ta of the semiconductor wafer W remaining after machining when the semiconductor element E is thin, and a thickness Tb of the semiconductor wafer W remaining after machining when the semiconductor element E is thick. The thickness Tb is larger than the thickness Ta. Thus, as in FIG. 7, chipping occurs near the semiconductor element E on the lower surface of the semiconductor wafer W when the semiconductor element E is thick.

However, in the first embodiment, as illustrated in FIG. 4B, variance of the trimming depth D due to the thickness of the semiconductor element E can be prevented by monitoring the thickness of the semiconductor wafer W at machining start.

### Second Embodiment

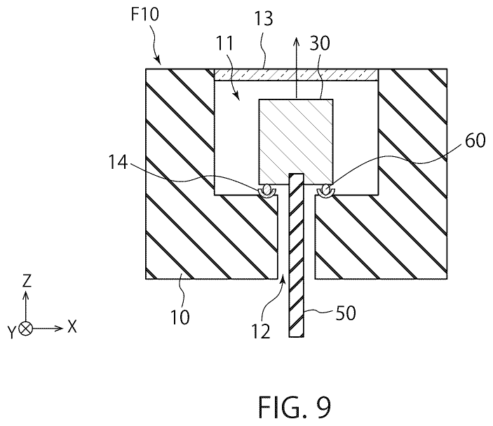

FIG. 9 is a cross-sectional view illustrating an example of the configuration of the table 10 according to a second embodiment. The second embodiment is different from the first embodiment in that a rotation body and a rail are provided.

The semiconductor manufacturing apparatus 1 further includes a rotation body 60.

The rotation body 60 is provided between a surface in the recessed part 11 and the sensor 30 and supports the sensor 30. In the example illustrated in FIG. 9, the rotation body 60 is provided between a bottom surface in the recessed part 11 and the sensor 30. The rotation body 60 is attached to, for example, the sensor 30.

The rotation body 60 contacts the surface in the recessed part 11 and is rotatable in accordance with rotation of the table 10. The rotation body 60 rotates as the table 10 rotates. Since the rotation body 60 is provided, the position of the sensor 30 can be further stabilized independently from rotation of the table 10. Accordingly, machining can be further highly accurately performed.

The table 10 further includes a rail 14. The rail 14 is provided on the surface in the recessed part 11 and contacts the rotation body 60. In the example illustrated in FIG. 9, the rail 14 is provided on the bottom surface of the recessed part 11. Similarly to the recessed part 11, the rail 14 is provided round the outer periphery of the semiconductor wafer W.

Since the rail 14 is provided, rotation of the rotation body 60 and support of the sensor 30 can be more appropriately performed. Accordingly, machining can be further highly accurately performed.

As in the second embodiment, a rotation body and a rail may be provided. The semiconductor manufacturing apparatus 1 according to the second embodiment can achieve the same effects as in the first embodiment.

### Third Embodiment

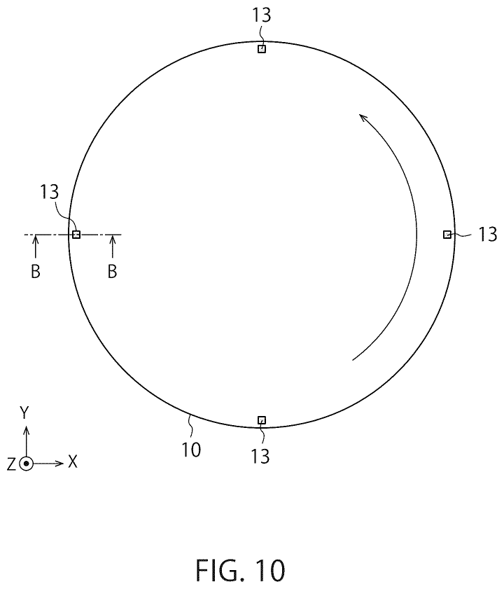

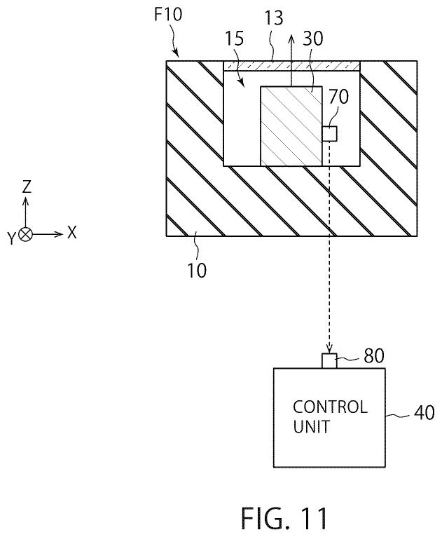

FIG. 10 is a top view illustrating an example of the configuration of the table 10 according to a third embodiment. FIG. 11 is a cross-sectional view illustrating the example of the configuration of the table 10 according to the third embodiment. Line B-B in FIG. 10 indicates a section corresponding to the cross-sectional view in FIG. 11.

The third embodiment is different from the first embodiment in that the result of the measurement by the sensor 30 is transmitted and received through wireless communication.

As illustrated in FIG. 11, the sensor 30 is provided inside the table 10.

The semiconductor manufacturing apparatus 1 further includes a wireless transmitting unit 70 and a wireless receiving unit 80.

The wireless transmitting unit 70 wirelessly transmits the result of the measurement by the sensor 30. The wireless transmitting unit 70 is provided, for example, near the sensor 30.

The wireless receiving unit 80 wirelessly receives the result of the measurement by the sensor 30 from the wireless transmitting unit 70. The wireless receiving unit 80 is provided, for example, at the control unit 40.

The table 10 includes a recessed part 15. The recessed part 15 is provided at the surface F10. The recessed part 15 has a width in the X direction and a depth in the Z direction with which the recessed part 15 can house the sensor 30 and the wireless transmitting unit 70. The recessed part 15 is an example of a second recessed part.

The sensor 30 is fixed in the recessed part 15. The sensor 30 and the wireless transmitting unit 70 are, for example, embedded in the recessed part 15. Accordingly, the sensor 30 rotates together with the table 10. For example, a vibration absorption member may be provided between the table 10 and the sensor 30.

As illustrated in FIG. 10, a plurality of transparent parts 13 are provided at intervals along the outer periphery near the outer peripheral end part of the table 10. The recessed part 15 is provided at a substantially same position as each transparent part 13 in FIG. 10. Accordingly, the recessed parts 15 and the transparent parts 13 are provided at intervals along a substantially circular ring centered at the center (central axis Ax) of the table 10 when viewed in the Z direction. The recessed parts 15 are trenches.

The number of recessed parts 15 corresponds to the number of sensors 30. In the example illustrated in FIG. 10, four sensors 30 are provided.

Each sensor 30 rotates together with the table 10 and measures the thickness of the semiconductor wafer W at a timing when a blade BL is positioned above the sensor 30. Thus, in the third embodiment, the thickness of the semiconductor wafer W can be monitored and adjusted at a timing when each sensor 30 is positioned directly below the blade BL as the table 10 rotates. In the example illustrated in FIG. 10, the four sensors 30 are provided at up, down, right, and left positions, respectively, on the table 10 when viewed in the Z direction. In this case, the thickness of the semiconductor wafer W is monitored and adjusted each time the table 10 rotates ¼ round.

In the third embodiment, the number of timings when the thickness of the semiconductor wafer W can be adjusted is smaller than in the first embodiment. In a case where the frequency of adjustment of the semiconductor wafer W is low, in other words, in a case where abrasion of the cutting edge of the blade BL slowly progresses, the thickness of the semiconductor wafer W can be adjusted according to the third embodiment, substantially similarly to the first embodiment.

As in the third embodiment, the result of the measurement by the sensor 30 may be transmitted and received through wireless communication. The semiconductor manufacturing apparatus 1 according to the third embodiment can achieve the same effects as in the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a table having a first surface on which a processing target object is placed and being rotatable about a rotational axis in a first direction substantially orthogonal to the first surface;
a shaft rotatably and movably holding a blade that machines the processing target object;
a sensor configured to measure a thickness of the processing target object in a region to be machined by the blade; and
a first control unit configured to control rotation and movement of the shaft and control movement of the blade in the first direction based on a result of the measurement by the sensor.

2. The semiconductor manufacturing apparatus according to claim 1, wherein
the first control unit moves downward the blade, which is positioned above the sensor, in the first direction while rotating the blade during stop of rotation of the table, and
the first control unit stops the downward movement of the blade when the result of the measurement by the sensor is equal to or smaller than a first predetermined thickness.

3. The semiconductor manufacturing apparatus according to claim 2, further comprising a second control unit configured to control rotation of the table, wherein the second control unit starts rotation of the table when the result of the measurement by the sensor is equal to or smaller than the first predetermined thickness.

4. The semiconductor manufacturing apparatus according to claim 2, wherein the number of the sensors corresponds to the number of the blades.

5. The semiconductor manufacturing apparatus according to claim 1, wherein the first control unit moves downward the blade in the first direction when the result of the measurement by the sensor is equal to or larger than a second predetermined thickness during rotation of the blade and the table.

6. The semiconductor manufacturing apparatus according to claim 5, wherein the sensor is constantly positioned below the blade during rotation of the table.

7. The semiconductor manufacturing apparatus according to claim 5, wherein the sensor rotates together with the table and measures the thickness of the processing target object at a timing when the blade is positioned above the sensor.

8. The semiconductor manufacturing apparatus according to claim 1, wherein
the sensor is provided inside the table, and
the semiconductor manufacturing apparatus further includes a structural body provided to penetrate through the table and supporting the sensor.

9. The semiconductor manufacturing apparatus according to claim 1, wherein
the sensor is provided inside the table, and
the table includes a first recessed part provided at the first surface such that the sensor is separated from the table that is rotating.

10. The semiconductor manufacturing apparatus according to claim 9, further comprising a rotation body that contacts a surface in the first recessed part and is rotatable in accordance with rotation of the table, wherein the rotation body supports the sensor.

11. The semiconductor manufacturing apparatus according to claim 10, wherein the table further includes a rail provided on the surface in the first recessed part and contacting the rotation body.

12. The semiconductor manufacturing apparatus according to claim 1, further comprising:
a wireless transmitting unit configured to wirelessly transmit the result of the measurement by the sensor; and
a wireless receiving unit configured to wirelessly receive the result of the measurement by the sensor from the wireless transmitting unit.

13. The semiconductor manufacturing apparatus according to claim 12, wherein the sensor is fixed in a second recessed part provided at the first surface.

14. The semiconductor manufacturing apparatus according to claim 1, wherein the sensor is an optical sensor or an ultrasonic sensor.

15. The semiconductor manufacturing apparatus according to claim 1, wherein the region to be machined by the blade is an outer peripheral end part of the processing target object when viewed in the first direction.
